(19) United States
(12) Patent Application Publication
(10) Pub. No.: US 2008/0032483 A1
(43) Pub. Date: Feb. 7, 2008

(54) Trench isolation methods of semiconductor device

(75) Inventors: Hyuk-Ju Ryu, Seoul (KR); Heon-Jong Shin, Yongin-si (KR); Hee-Sung Kang, Seongnam-si (KR); Choong-Ryul Ryou, Suwon-si (KR); Mu-Kyeng Jung, Suwon-si (KR); Kyung-Soo Kim, Seongnam-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/973,044

(22) Filed: Oct. 5, 2007

Related U.S. Application Data
(62) Division of application No. 11/358,454, filed on Feb. 21, 2006.

(30) Foreign Application Priority Data
Feb. 21, 2005 (KR) 10-2005-0014241

(51) Int. Cl. H01L 21/78

(52) U.S. Cl. 438/433; 257/E21.54

(57) ABSTRACT

In a trench isolation method, a semiconductor substrate having an N-MOS region and a P-MOS region is prepared. A first mask pattern exposing an N-MOS field region is formed on the N-MOS region, and a second mask pattern exposing a P-MOS field region is formed on the P-MOS region. A first photoresist pattern is formed to cover the P-MOS region and expose the N-MOS region. First impurity ions are implanted into the N-MOS region, using the first mask pattern and the first photoresist pattern as ion implantation masks, thereby forming a first impurity layer in the N-MOS field region. In this case, a portion of the first impurity layer is formed to extend below the first mask pattern. The first photoresist pattern is removed. The semiconductor substrate is etched using the first and second mask patterns as etch masks, thereby forming trenches in the N-MOS field region and the P-MOS field region and concurrently, forming a first impurity pattern of the first impurity layer remaining below the first mask pattern. A trench isolation layer filling the trenches is then formed.

### CROSS-REFERENCE TO RELATED APPLICATION

This application is a divisional of U.S. application Ser. No. 11/358,454, filed on Feb. 21, 2006, which relies for priority upon Korean Patent Application No. 10-2005-0014241, filed on Feb. 21, 2005, the disclosure of which is hereby incorporated herein by reference in its entirety as if set forth fully herein.

### BACKGROUND OF INVENTION

1. Technical Field

The present invention relates to a method of fabricating a semiconductor device, and more particularly, to a trench isolation method for fabrication of a semiconductor device.

2. Discussion of the Related Art

For high integration of semiconductor devices, isolation technology for isolating discrete devices electrically and structurally is one of the essential technologies in the semiconductor fabrication process to enable the discrete devices to perform their own designated functions without interference from neighboring devices. With enhanced isolation technology, highly-integrated semiconductor devices can be realized as the trend toward scaling down of the technology of discrete devices continues to occur. In order to increase the integration degree of a highly-integrated device, the dimensions of a discrete device must be reduced, and concurrently, the width and area of an isolation region between two neighboring devices must also be reduced. The isolation technology determines the integration degree of a highly-integrated device, and is an important factor for the resulting reliability of the electrical performance of such a device.

Recently, trench isolation technology widely used in semiconductor fabrication has resolved a well-known problem referred to as a “bird's beak” problem caused during a conventional local oxidation of silicon (LOCOS) process. The trench isolation technology realizes isolation and insulation between devices by forming a trench defining an active region and filling the trench with an insulating material.

A trench isolation method for forming a trench isolation layer using the trench isolation technology is widely known. A typical method of forming a trench isolation layer includes forming a trench that defines active regions in a semiconductor substrate, forming an insulating layer such as a silicon oxide layer that buries the trench, and planarizing the insulating layer using a chemical mechanical polishing (CMP) process, thereby forming a trench isolation layer. A groove is formed at the upper corner of the trench isolation layer formed in the manner described above so that the upper sidewalls of the active regions adjacent to the upper corner of the trench isolation layer can be exposed.

FIG. 1 is a sectional view illustrating a semiconductor device fabricated using a conventional trench isolation method.

Referring to FIG. 1, a first trench isolation layer 3a and a second trench isolation layer 3b defining a first active region 4a and a second active region 4b respectively are disposed in a semiconductor substrate 1. A P-well 5a and an N-well 5b are disposed in the semiconductor substrate of the first active region 4a and the second active region 4b respectively. The P-well 5a is a region doped with impurity ions of Group III, and the N-well 5b is a region doped with impurity ions of Group V. The first trench isolation layer 3a and the second trench isolation layer 3b may be formed of silicon oxide layers.

A gate electrode 10a for an N-MOS transistor is disposed on the semiconductor substrate over the P-well 5a. In this case, the gate electrode 10a for the N-MOS transistor can be disposed to extend over the first trench isolation layer 3a. Similarly, a gate electrode 10b for a P-MOS transistor is disposed on the semiconductor substrate over the N-well 5b. In this case, the gate electrode 10b for the P-MOS transistor can be disposed to extend over the second trench isolation layer 3b. Gate oxide layers 7a, 7b are interposed between the wells 5a, 5b, of the semiconductor substrate, and the gate electrodes 10a, 10b. In a plan view, N-type source/drain regions (not shown) are disposed in the semiconductor substrate of the P-well 5a disposed on both sides of the gate electrode 10a for an N-MOS transistor. Similarly, P-type source/drain regions (not shown) are disposed in the semiconductor substrate of the N-well 5b disposed on both sides of the gate electrode 10b for a P-MOS transistor. The gate electrode 10a for an N-MOS transistor disposed on the semiconductor substrate of the P-well 5a and the N-type source/drain regions (not shown) constitute an N-MOS transistor. The gate electrode 10b for a P-MOS transistor disposed on the semiconductor substrate of the N-well 5b and the P-type source/drain regions (not shown) constitute a P-MOS transistor.

As shown in FIG. 1, grooves can be formed on the upper corners of the trench isolation layers 3a, 3b formed using the conventional trench isolation process to confine the wells 5a, 5b. That is, the thickness of the gate oxide layers 7a, 7b in the region of the upper interface areas A, B of the trench isolation layers 3a, 3b and the wells 5a, 5b can be less than the thicknesses of the layers 7a, 7b above the central regions of the wells 5a, 5b as shown in FIG. 1.

When the MOS transistors structured as above are in a state of operation, an electric field may be concentrated at the upper corners of the wells 5a, 5b adjacent to the trench isolation layers 3a, 3b so that a parasitic current flows. Thus, a threshold current at the upper corners of the wells 5a, 5b is decreased. A main device can therefore be formed at the center regions of the wells 5a, 5b, where the main device is turned on at a threshold voltage. In addition, a parasitic device can be formed at the boundary regions of the wells 5a, 5b, and the parasitic device is turned on at a voltage lower than the threshold voltage. An inverse narrow width effect can therefore be present.

Furthermore, if the channel width of the MOS transistors is further reduced with the continued trend toward high integration of semiconductor devices, concentration variation of the impurity ions in the wells 5a, 5b where the channel is formed may strongly influence the threshold voltage of the MOS transistors. Specifically, in the case of an N-MOS transistor, the impurity ion concentration at the upper corner of the P-well 5a adjacent to the first trench isolation layer 3a may be decreased in subsequent annealing processes during semiconductor device fabrication. That is, boron (B) normally used for the impurity ions of the P-well 5a is diffused into the neighboring silicon oxide layer by heat so that the concentration may be further decreased. As such, since the concentration of the impurity ions at the upper corners of the P-well 5a adjacent the first trench isolation layer 3a is decreased, the threshold voltage of the N-MOS transistor having a narrow channel width may be more unstable. In the meantime, in the case of the P-MOS transistor, the impurity ions at the upper corners of the N-well 5b adjacent the second trench isolation layer 3b may be highly concentrated. That is, when phosphorus (P) used for the impurity ions of the N-well 5b is concentrated at the upper corner of the N-well 5b, the concentration of the phosphorus (P) is increased. Thus, the threshold voltage at the boundary of the N-well 5b is also increased. As a result, the threshold voltage of the resulting P-MOS transistor is unstable. As described above, instability in the threshold voltage of a MOS transistor, can negatively affect device characteristics and device reliability.

In order to improve device characteristics and device reliability, an ion implantation process can be performed after forming the trench. That is, when implanting impurity ions on the sidewalls of the trench adjacent to the P-well, implantation of impurity ions on the sidewalls of the trench adjacent to the N-well is prevented by forming a photoresist layer in the trench adjacent the N-well. Since the aspect ratio of the trench is increased with higher integration of semiconductor devices, it is increasingly difficult to completely remove the photoresist layer formed in the trench. As a result, a portion of photoresist layer can remain in the bottom of the trench. Any photoresist layer remaining in the trench can further negatively affect device characteristics and decrease device reliability.

### SUMMARY OF THE INVENTION

The present invention is directed to trench isolation methods that improve characteristics and reliability of a semiconductor device.

In accordance with one aspect, the present invention provides a trench isolation method of a semiconductor device in which impurity ions are implanted before forming a trench. The method includes preparing a semiconductor substrate having an N-MOS region and a P-MOS region. A first mask pattern exposing an N-MOS field region is formed on the N-MOS region, and a second mask pattern exposing a P-MOS field region is formed on the P-MOS region. A first photoresist pattern is formed to cover the P-MOS region and expose the N-MOS region. First impurity ions are implanted into the N-MOS region, using the first mask pattern and the first photoresist pattern as ion implantation masks, thereby forming a first impurity layer in the N-MOS field region. In this case, a portion of the first impurity layer is formed to extend below the first mask pattern. The first photoresist pattern is removed. The semiconductor substrate is etched using the first and second mask patterns as etch masks, thereby forming trenches in the N-MOS field region and the P-MOS field region and concurrently, forming a first impurity pattern of the first impurity layer remaining below the first mask pattern. A trench isolation layer filling the trenches is formed.

In accordance with exemplary embodiments of the present invention, the first and second mask patterns may be composed of a pad oxide pattern and a hard mask pattern, which are sequentially stacked. In this case, the pad oxide pattern may be formed of a silicon oxide layer. The hard mask pattern may be formed of a silicon nitride layer or silicon oxynitride (SiON) layer.

In accordance with exemplary embodiments of the present invention, the first impurity ions may be impurity ions of Group III. In this case, the first impurity ions may be implanted by an ion implantation method using about 0.2 to about 100 keV of energy. The first impurity ions may be implanted at a dose of about 1×10¹¹ to about 1×10¹⁶ ions/cm².

In accordance with exemplary embodiments of the present invention, the method further includes forming a second photoresist pattern covering the N-MOS region and exposing the P-MOS region; implanting second impurity ions into the P-MOS region, using the second photoresist pattern and the second mask pattern as ion implantation masks, thereby forming a second impurity layer in the P-MOS field region, in which a portion of the second impurity layer may be formed to extend below the second mask pattern; and removing the second photoresist pattern. In this case, concurrently with the formation of the trenches, the method may further include forming a second impurity pattern of the second impurity layer remaining below the second mask pattern. Here, the second impurity ions may be boron (B), boron difluoride (BF₂), arsenic (As), phosphorus (P), or indium (In). The second impurity ions may be implanted by an ion implantation method using about 0.2 to about 100 keV of energy. The second impurity ions may be implanted at a dose of about 1×10¹¹ to about 1×10¹⁶ ions/cm². After removing the second photoresist pattern, the method may further include annealing the semiconductor substrate having the first and second impurity layers formed thereon. The annealing operation may be performed at a temperature of about 600° C. to about 1000° C.

In accordance with exemplary embodiments of the present invention, the operation of forming the trench isolation layer may include forming an insulating layer for isolation filling the trenches on an overall surface of the semiconductor substrate having the trenches; planarizing the insulating layer for isolation until the first and second mask patterns are exposed; and removing the exposed mask patterns, thereby exposing the semiconductor substrate. In this case, the trench isolation layer may be formed of a silicon oxide layer. Here, after forming the trenches, the method may further include forming a buffer oxide layer on inner walls of the trenches; and forming a conformal insulating liner on an overall surface of the semiconductor substrate having the buffer oxide layer.

In accordance with another aspect; the present invention provides a trench isolation method of a semiconductor device in which impurity ions are implanted after forming preliminary trenches. The method includes preparing a semiconductor substrate having an N-MOS region and a P-MOS region. A first mask pattern exposing an N-MOS field region on the N-MOS region is formed, and a second mask pattern exposing a P-MOS field region on the P-MOS region is formed. The semiconductor substrate of the N-MOS field region and the P-MOS field region exposed by the first and second mask patterns respectively is etched, thereby forming a first preliminary trench and a second preliminary trench. A first photoresist pattern covering the P-MOS region and exposing the N-MOS region is formed on the semiconductor substrate having the first and second preliminary trenches. First impurity ions are implanted into inner walls of the first preliminary trench, using the first mask pattern and the first photoresist pattern as ion implantation masks, thereby forming a first impurity layer. In this case, a portion of the first impurity layer is formed to extend below the first mask pattern. The first photoresist pattern is removed. An anisotropic etch process is performed on the semiconductor substrate having the first and second preliminary trenches, using the first and second mask patterns as etch masks, thereby forming a first trench and a second trench, and concurrently, forming a first impurity pattern of the first impurity layer remaining below the first mask pattern. A trench isolation layer is formed to fill the first and second trenches.

In accordance with exemplary embodiments of the present invention, the first and second mask patterns may be composed of a pad oxide pattern and a hard mask pattern, which are sequentially stacked. In this case, the pad oxide pattern may be formed of a silicon oxide layer. The hard mask pattern may be formed of a silicon nitride layer or silicon oxynitride (SiON) layer.

In accordance with exemplary embodiments of the present invention, the first impurity ions may be impurity ions of Group III. In this case, the first impurity ions may be implanted by an ion implantation method using about 0.2 to about 100 keV of energy. The first impurity ions may be implanted at a dose of about 1×10¹¹ to about 1×10¹⁶ ions/cm².

In accordance with exemplary embodiments of the present invention, the method may further include forming a second photoresist pattern covering the N-MOS region and exposing the P-MOS region; implanting second impurity ions into inner walls of the second preliminary trench, using the second photoresist pattern and the second mask pattern as ion implantation masks, thereby, forming a second impurity layer, in which a portion of the second impurity layer may be formed to extend below the second mask pattern; and removing the second photoresist pattern. The method may further include forming a second impurity pattern of the second impurity layer remaining below the second mask pattern concurrently with the formation of the second trench. Here, the second impurity ions may be boron (B), boron difluoride (BF₂), arsenic (As), phosphorus (P), or indium (In). The second impurity ions may be implanted by an ion implantation method using about 0.2 to about 100 keV of energy. The second impurity ions may be implanted at a dose of about 1×10¹¹ to about 1×10¹⁶ ions/cm². After removing the second photoresist pattern, the method may further include annealing the semiconductor substrate having the first and second impurity layers formed thereon. The annealing operation may be performed at a temperature of about 600° C. to about 1000° C.

In accordance with exemplary embodiments of the present invention, the operation of forming the trench isolation layer may include forming an insulating layer for isolation filling the first and second trenches on an overall surface of the semiconductor substrate having the first and second trenches; planarizing the insulating layer for isolation until the first and second mask patterns are exposed; and removing the exposed first and second mask patterns, thereby exposing the semiconductor substrate. Further, the trench isolation layer may be formed of a silicon oxide layer. After forming the first and second trenches, the method may further include forming a buffer oxide layer on inner walls of the first and second trenches; and forming a conformal insulating liner on an overall surface of the semiconductor substrate having the buffer oxide layer.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a sectional view illustrating a conventional semiconductor device;

FIG. 2 is a plan view illustrating a typical semiconductor device;

FIGS. 3A to 3F are sectional views illustrating a trench isolation method of a semiconductor device according to an embodiment of the present invention; and

FIGS. 4A to 4E are sectional views illustrating a trench isolation method of a semiconductor device according to another embodiment of the present invention.

### DETAILED DESCRIPTION OF THE INVENTION

The present invention will now be described more fully hereinafter with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. Like numbers refer to like elements throughout the specification.

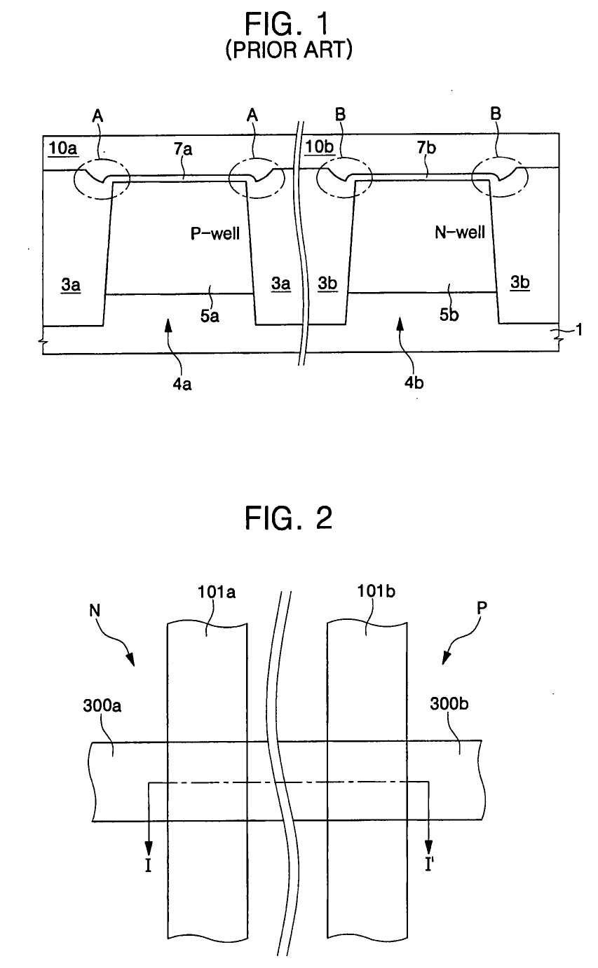

FIG. 2 is a plan view illustrating a typical semiconductor device.

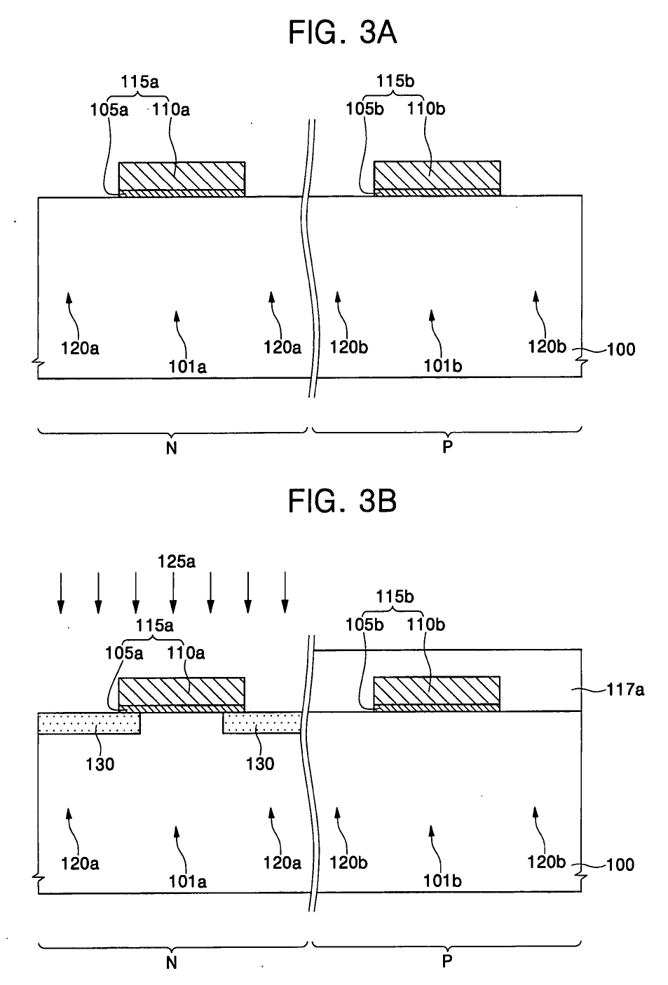

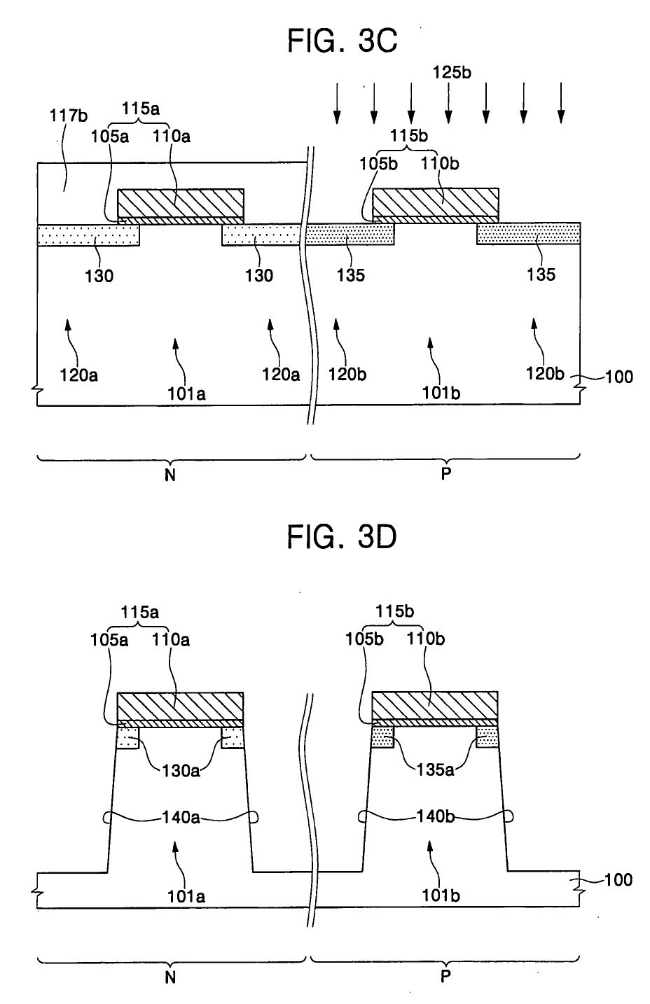

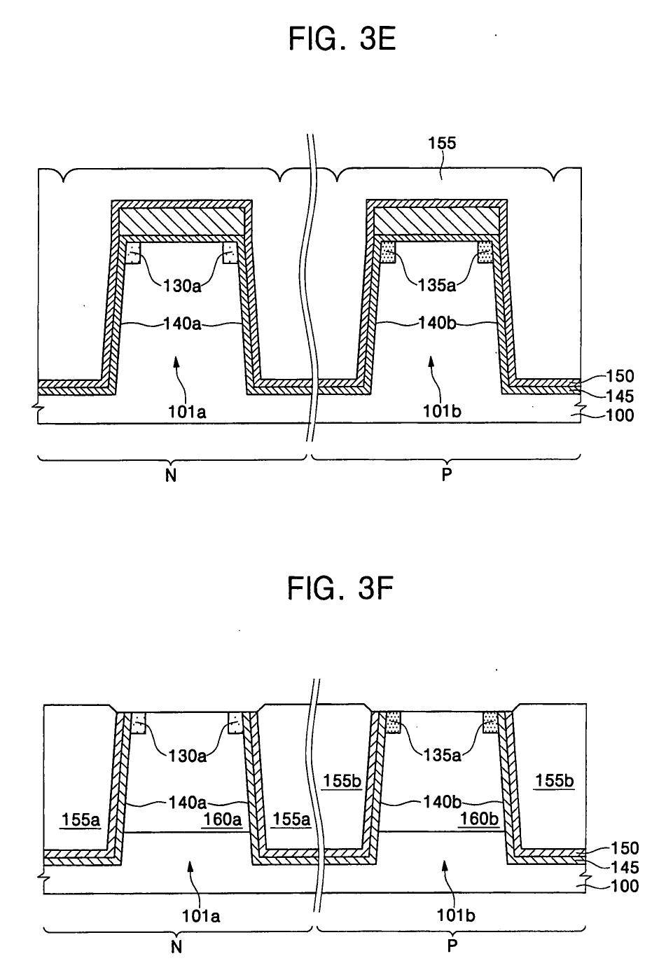

FIGS. 3A to 3F are sectional views illustrating a trench isolation method of a semiconductor device according to an embodiment of the present invention taken along a line of I-I′ of FIG. 2.

Referring to FIGS. 2 and 3A, a semiconductor substrate 100 having an N-MOS region N and a P-MOS region P is prepared. A first mask pattern 115a exposing an N-MOS field region 120a is formed on the N-MOS region N, and concurrently, a second mask pattern 115b exposing a P-MOS field region 120b is formed on the P-MOS region P. Here, the first mask pattern 115a is formed on the semiconductor substrate on a first active region 101a defined by the N-MOS field region 120a, and the second mask pattern 115b is formed on the semiconductor substrate on a second active region 101b defined by the P-MOS field region 120b. The first mask pattern 115a comprises, for example, a pad oxide pattern 105a and a hard mask pattern 110a, which are sequentially stacked. Similarly, the second mask pattern 115b comprises, for example, a pad oxide pattern 105b and a hard mask pattern 110b, which are sequentially stacked. To form the first and second mask patterns, a pad oxide layer and a hard mask layer are sequentially formed on the semiconductor substrate 100. The pad oxide layer comprises, for example, a thermal oxide layer. The pad oxide layer may be formed to alleviate stress caused due to difference of the thermal expansion coefficients between the semiconductor substrate 100 and the hard mask layer. The hard mask layer comprises, for example, a material layer having an etch selectivity with respect to the semiconductor substrate 100. For example, the hard mask layer may be formed of a silicon nitride layer or a silicon oxynitride (SiON) layer by a chemical vapor deposition (CVD) method. The hard mask layer and the pad oxide layer are patterned, thereby sequentially forming hard mask patterns and pad oxide patterns on the semiconductor substrate of the first active region 101a and the second active region 101b.

Referring to FIGS. 2 and 3B, a first photoresist pattern 117a is formed to cover the P-MOS region P while exposing the N-MOS region N. First impurity ions 125a are implanted into the semiconductor substrate of the exposed N-MOS field region 120a, using the first photoresist pattern 117a and the first mask pattern 115a as ion implantation masks, thereby forming a first impurity layer 130. In this case, a predetermined portion of the first impurity layer 130 can be formed to extend below the first mask pattern 115a. The first impurity ions 125a can be implanted by an ion implantation method. The ion implantation method may use a tilt ion implantation method. The first impurity ions 125a may be impurity ions of Group III of the periodic table. For example, the first impurity ions 125a may be boron (B), boron difluoride (BF₂), or indium (In). The first impurity ions 125a may be implanted into the semiconductor substrate by an ion implantation method using 0.2 to 100 keV of energy. The first impurity ions 125a may be implanted into the semiconductor substrate at a dose of 1×10¹¹ to 1×10¹⁶ ions/cm² with choice of many directions, depending on the application.

Referring to FIGS. 2 and 3C, the first photoresist pattern 117a (FIG. 3B) is removed, for example, using an ashing process.

A second photoresist pattern 117b is formed to cover the N-MOS region N and expose the P-MOS region P. Second impurity ions 125b are implanted into the semiconductor substrate of the exposed P-MOS field region 120b using the second photoresist pattern 117b and the second mask pattern 115b as ion implantation masks, thereby forming a second impurity layer 135. The second impurity ions 125b may be implanted by an ion implantation method. The ion implantation method may use a tilt ion implantation method. The second impurity ions 125b may be impurity ions of Group III or Group V of the periodic table. For example, the second impurity ions 125b may be boron (B), boron difluoride (BF₂), phosphorus (P), or arsenic (As). The second impurity ions 125b may be implanted into the semiconductor substrate by an ion implantation method using 0.2 to 100 keV of energy. The second impurity ions 125b may be implanted into the semiconductor substrate at a dose of 1×10¹¹ to 1×10¹⁶ ions/cm² with choice of many directions, depending on the application.

In the above embodiment, it has been explained that the ion implantation process of the second impurity ions 125b was performed following the ion implantation process of the first impurity ions 125a. In an alternative embodiment, equally applicable to the present invention, the ion implantation process of the first impurity ions 125a can optionally be performed following the ion implantation process of the second impurity ions 125b.

Referring to FIGS. 2 and 3D, the second photoresist pattern 117b (FIG. 3C) is removed, for example, using an ashing process.

The semiconductor substrate including the first impurity layer 130 and the second impurity layer 135 is next annealed, for example, using a rapid thermal process (RTP) or a furnace thermal process. The annealing can be performed, for example, at a temperature of 600° C. to 1000° C. The impurity layers 130, 135 are stabilized by the annealing process.

The semiconductor substrate of the N-MOS field region 120a and the P-MOS field region 120b is next etched to a predetermined depth, using the mask patterns 115a, 115b as etch masks, thereby forming a first trench 140a and a second trench 140b, and concurrently, forming a first impurity pattern 130a remaining below the first mask pattern 115a and a second impurity pattern 135a remaining below the second mask pattern 115b. That is, the first impurity layer remains in the upper corners of the first trench 140a in the semiconductor substrate so as to form the first impurity pattern 130a. Also, the second impurity layer remain in contact with the upper corners of the second trench 140b in the semiconductor substrate so as to form the second impurity pattern 135a. Here, the first trench 140a and the second trench 140b, which are formed in the semiconductor substrate of the N-MOS field region 120a and the P-MOS field region 120b respectively, are shown in the cross-sectional diagrams as being discrete trenches, but they may be formed of a common, connected trench.

Referring to FIGS. 2 and 3E, a buffer oxide layer 145 is formed on the surface of the inner walls of the first trench 140a and the second trench 140b. The buffer oxide layer 145 is formed, for example, of a thermal oxide layer. Since the buffer oxide layer 145 is formed of a thermal oxide layer, any etch damage to the semiconductor substrate 100 that may occur during the etch process of forming the trenches 140a, 140b can be cured. An insulating liner 150 is then formed on the overall surface of the resulting structure having the buffer oxide layer 145. The insulating liner 150 is formed, for example, of a silicon nitride layer, which prevents that the inner walls of the trenches 140a, 140b from again being thermally oxidized during a subsequent annealing process. An insulating layer 155 is formed on the semiconductor substrate having the insulating liner 150 to fill the trenches 140a, 140b. The insulating layer 155 for isolation is formed, for example, of a silicon oxide layer. For example, the insulating layer 155 for isolation may be formed of a high density plasma oxide layer.

Referring to FIGS. 2 and 3F, the insulating layer 155 for isolation (FIG. 3E) is planarized until the upper surface of the mask patterns 115 (FIG. 3e) is exposed, thereby forming a first trench isolation layer 155a and a second trench isolation layer 155b in the first trench 140a and the second trench 140b respectively. The planarization process is performed, for example, using a chemical mechanical polishing (CMP) process. The mask patterns 115 (FIG. 3E) are then removed. A first impurity pattern 130a is present in the semiconductor substrate of the first active region 101a adjacent to the upper edges of the first trench isolation layer 155a, and a second impurity pattern 135a is present in the semiconductor substrate of the second active region 101b adjacent to the upper edges of the second trench isolation layer 155b.

Then, a P-well 160a and an N-well 160b may be formed in the semiconductor substrate of the first active region 101a and the second active region 101b respectively. Alternatively, the P-well 160a or the N-well 160b may be formed before, or during, the trench isolation process is performed.

A gate insulating layer (not shown) and gate electrodes 300a, 300b (FIG. 2) may then be formed, followed by additional typical semiconductor fabrication processes to complete the manufacture a semiconductor device including an N-MOS transistor and a P-MOS transistor.

The first impurity pattern 130a functions as a source of the impurity ions for the P-well 160a so as to prevent the concentration of the impurity ions in the P-well 160a from becoming non-uniform. Further, the first impurity pattern 130a prevents the threshold voltage of an N-MOS transistor to be formed from being non-uniform in the channel width direction. Further, the first impurity pattern 130a suppresses generation of a parasitic current at the edge of a channel region in the channel width direction of the N-MOS transistor.

The second impurity pattern 135a functions to prevent a file-up phenomenon that results from over-concentration of impurity ions generated at the upper corners of the N-well 106b adjacent to the second trench isolation layer 155b. In specific, in the case that the second impurity pattern 135a is composed of impurity ions of Group III, the second impurity pattern 135a can suppress file-up of the impurity ions at the upper corner of the N-well 160b so as to stabilize the threshold voltage of the resulting P-MOS transistor. Alternatively, in the case that the second impurity pattern 135a is composed of impurity ions of Group V, the second impurity pattern 135a can prevent a parasitic current generated at the upper corners of the N-well 160b adjacent to the second trench isolation layer 155b. Whether the second impurity pattern 135a is composed of impurity ions of Group III or V may be determined in accordance with characteristics of a semiconductor device to be manufactured. That is, if the file-up phenomenon at the upper corners of the N-well 160b is apparent, the second impurity pattern 135a may be composed of impurity ions of Group III. However, if a parasitic current is large at the upper corners of the N-well 160b, the second impurity pattern 135a may be composed of impurity ions of Group V.

Furthermore, by implanting the first and second impurity ions 125a, 125b before the first trench 140a and the second trench 140b are formed, the problems involved with residual photoresist are prevented. As a result, device characteristics and reliability can be improved.

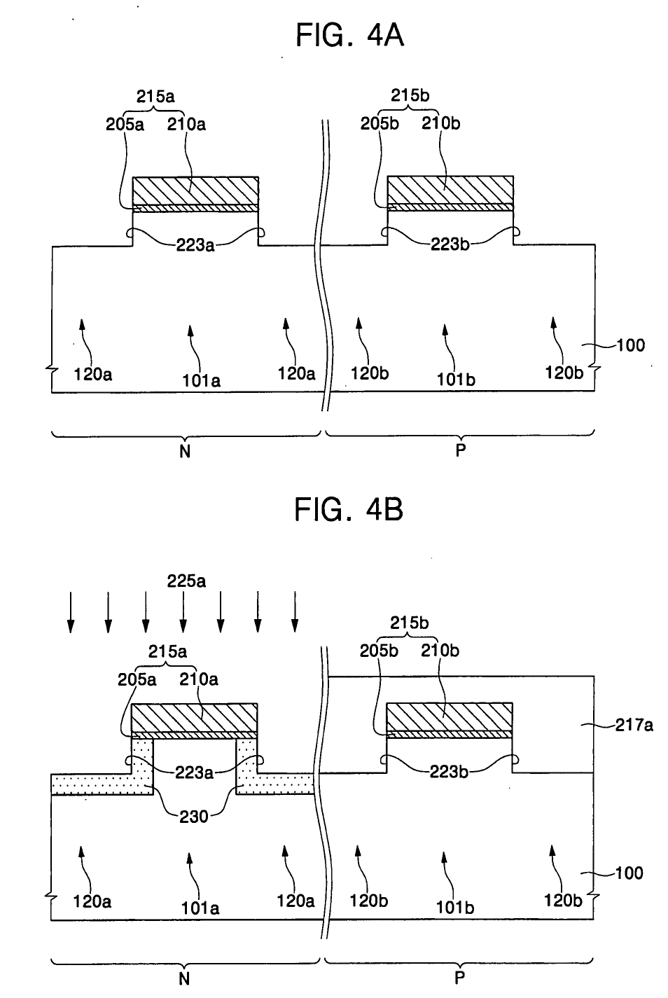

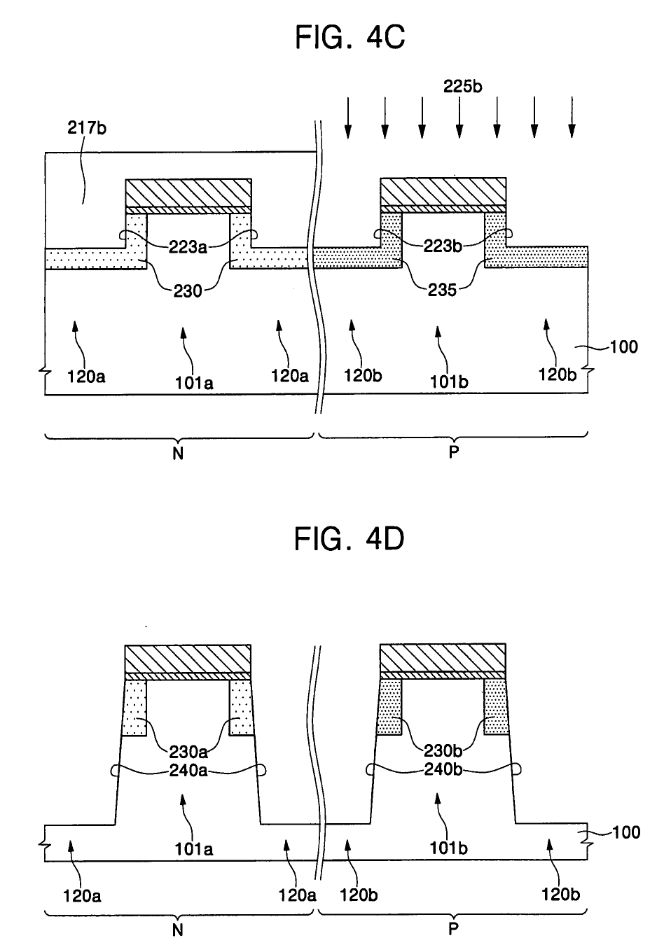

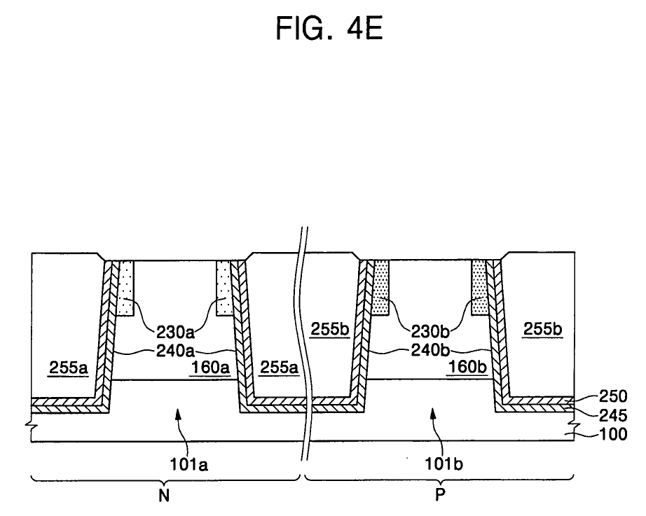

FIGS. 4A to 4E are sectional views illustrating a trench isolation method of a semiconductor device according to another embodiment of the present invention, taken along line of I-I′ of FIG. 2.

Referring to FIGS. 2 and 4A, a semiconductor substrate 100 having an N-MOS region N and a P-MOS region P is prepared. A mask layer is formed on the semiconductor substrate 100. The mask layer may be composed of a pad oxide layer and a hard mask layer, which are sequentially stacked. The pad oxide layer is formed, for example, of a thermal oxide layer. The hard mask layer is formed, for example, of a silicon nitride layer or a silicon oxynitride (SiON) layer by a CVD method. Photoresist patterns (not shown) may be formed on the mask layer. The mask layer is etched using the photoresist patterns as an etch mask, thereby forming a first mask pattern 215a exposing the N-MOS field region 120a on the N-MOS region N, and forming a second mask pattern 215b exposing the P-MOS field region 120b on the P-MOS region P. Here, the first mask pattern 215a is formed on the semiconductor substrate of the first active region 101a defined by the N-MOS field region 120a, and the second mask pattern 215b is formed on the semiconductor substrate of the second active region 101b defined by the P-MOS field region 120b. The first mask pattern 215a comprises a pad oxide pattern 205a and a hard mask pattern 210a, which are sequentially stacked. Similarly, the second mask pattern 215b comprises a pad oxide pattern 205b and a hard mask pattern 210b, which are sequentially stacked.

The photoresist patterns formed on the first mask pattern 215a and the second mask pattern 215b are removed. Then, an etch process is performed on the exposed semiconductor substrate using the mask patterns 215 as an etch mask so as to etch the semiconductor substrate, thereby forming a first preliminary trench 223a and a second preliminary trench 223b.

Alternatively, an etch process may be performed to etch the exposed semiconductor substrate using the photoresist patterns formed on the first mask pattern 215a and the second mask pattern 215b as etch masks, thereby forming a first preliminary trench 223a and a second preliminary trench 223b.

The photoresist patterns are then removed.

Here, the first preliminary trench 223a and the second preliminary trench 223b have predetermined depths relative to the surface of the semiconductor substrate of the first active region 101a and the second active region 101b. The predetermined depth may be sufficiently deep so as to prevent any residue of photoresist patterns to be later formed from remaining in the preliminary trenches 223a, 223b in the case where the photoresist patterns are to be removed after the first preliminary trench 223a and the second preliminary trench 223b are formed.

Referring to FIGS. 2 and 4B, a first photoresist pattern 217a covering the P-MOS region P and exposing the N-MOS region N is formed on the semiconductor substrate having the preliminary trenches 223a, 223b. First impurity ions 225a are implanted into the inner walls and bottom of the first preliminary trench 223a of the N-MOS region N, using the first photoresist pattern 217a and the first mask pattern 215a as ion implantation masks, thereby forming a first impurity layer 230. A predetermined portion of the first impurity layer 230 is formed to extend below the first mask pattern 215a. Here, the first impurity ions 225a can be implanted by an ion implantation method. The ion implantation method may be performed using a tilt ion implantation method. The first impurity ions 225a may be impurity ions of Group III. For example, the first impurity ions 225a may be boron (B), boron difluoride (BF₂), or indium (In). The first impurity ions 225a may be implanted into the semiconductor substrate by an ion implantation method using 0.2 to 100 keV of energy. The first impurity ions 225a may be implanted into the semiconductor substrate at a dose of 1×10¹¹ to 1×10¹⁶ ions/cm² at a number of directions, depending on application.

Referring to FIGS. 2 and 4C, the first photoresist pattern 217a (FIG. 4B) is removed, for example, using an ashing process.

A second photoresist pattern 217b covering the N-MOS region N and exposing the P-MOS region P is formed on the semiconductor substrate having the preliminary trenches 223a, 223b. Then, second impurity ions are implanted into the inner walls of the second preliminary trench 223b of the P-MOS region P, using the second photoresist pattern 217b and the second mask pattern 215b as ion implantation masks, thereby forming a second impurity layer 235. A predetermined portion of the second impurity layer 235 is formed to extend below the second mask pattern 215b. The second impurity ions 225b may be implanted by an ion implantation method. The ion implantation method may use a tilt ion implantation method. The second impurity ions 225b may be impurity ions of Group III or Group V of the periodic table. For example, the second impurity ions 225b may be boron (B), boron difluoride (BF₂), phosphorus (P), or arsenic (As). The second impurity ions 225b may be implanted into the semiconductor substrate by an ion implantation method using 0.2 to 100 keV of energy. The second impurity ions 225b may be implanted into the semiconductor substrate at a dose of 1×10¹¹ to 1×10¹⁶ ions/cm² at a number of directions, depending on application.

In the example of FIGS. 4A-4C above, it has been described that the ion implantation process of the second impurity ions 225b is performed after the ion implantation process of the first impurity ions 225a was performed. In an alternative embodiment, the ion implantation process of the first impurity ions 225a may be performed after the ion implantation process of the second impurity ions 225b is performed.

Referring to FIGS. 2 and 4D, an anisotropic etch process is performed on the semiconductor substrate having the first preliminary trench 223a and the second preliminary trench 223b, using the first mask pattern 215a and the second mask pattern 215b as etch masks, thereby forming a first trench 240a and a second trench 240b extending from the first preliminary trench 223a and the second preliminary trench 223b respectively. In this case, the first impurity layer 230 (FIG. 4C) remains below the first mask pattern 215a so as to form a first impurity pattern 230a. The second impurity layer 235 (FIG. 4C) remains below the second mask pattern 215b so as to form a second impurity pattern 235a. That is, the first impurity pattern 230a remain on the sidewalls of the upper portion of the first trench 240a. Also, the second impurity pattern 235a remains on the sidewalls of the upper portion of the second trench 240b.

Referring to FIGS. 2 and 4E, a first trench isolation layer 255a and a second trench isolation layer 255b are formed to fill the first trench 240a and the second trench 240b. The first trench isolation layer 255a and the second trench isolation layer 255b may be formed using the method described above in reference to FIGS. 3E and 3F. A buffer oxide layer 245 and an insulating liner 250 may be sequentially formed between the trench isolation layers 255a, 255b, and the trenches 240a, 240b. The first trench isolation layer 255a and the second trench isolation layer 255b may be formed of a silicon oxide layer.

Then, a P-well 160a and an N-well 160b may be formed in the semiconductor substrate of the first active region 101a and the second active region 101b respectively as described in reference to FIG. 3F above.

As a result, since impurity ions are implanted after the preliminary trenches 223a, 223b are formed, impurity patterns can be formed in a more stable manner on the upper corners of the first active region 101a and the second active region 101b. The impurity patterns 230a, 235a formed as above may have the same function as that of the impurity patterns 130a, 135a as described in reference to FIG. 3F.

As described above, according to embodiments of the present invention, by implanting impurity ions of Group III into the upper corner of a first active region where a P-well is to be formed before trenches are formed, and by implanting impurity ions of Group III or V into the upper corner of a second active region where an N-well is to be formed, generation of an unstable threshold voltage or parasitic current on the substrate surface of the active regions at the interface regions with trench isolation layers is avoided. Further, the trench isolation methods according to embodiments of the present invention avoid the above-stated problem of any residual photoresist pattern material remaining in the trenches, a problem that can occur as a result of performing a photolithography process after the trench is formed in the conventional approach. According, device characteristics and reliability are improved by the present invention.

While this invention has been particularly shown and described with references to preferred embodiments thereof, it will be understood by those skilled in the art that various changes in form and details may be made herein without departing from the spirit and scope of the invention as defined by the appended claims.

What is claimed is:

1. A trench isolation method of a semiconductor device comprising:
preparing a semiconductor substrate having an N-MOS region and a P-MOS region;
forming a first mask pattern exposing an N-MOS field region on the N-MOS region, and forming a second mask pattern exposing a P-MOS field region on the P-MOS region;
etching the semiconductor substrate of the N-MOS field region and the P-MOS field region exposed by the first and second mask patterns respectively, thereby forming a first preliminary trench and a second preliminary trench;
forming a first photoresist pattern covering the P-MOS region and exposing the N-MOS region on the semiconductor substrate having the first and second preliminary trenches;
implanting first impurity ions into inner walls of the first preliminary trench, using the first mask pattern and the first photoresist pattern as ion implantation masks, thereby forming a first impurity layer, a portion of the first impurity layer being formed to extend below the first mask pattern;
removing the first photoresist pattern;
anisotropically etching the semiconductor substrate having the first and second preliminary trenches, using the first and second mask patterns as etch masks, thereby forming a first trench and a second trench, and concurrently, forming a first impurity pattern of the first impurity layer remaining below the first mask pattern; and
forming a trench isolation layer filling the first and second trenches.

2. The method according to claim 1, wherein the first and second mask patterns each comprise a pad oxide pattern and a hard mask pattern, which are sequentially stacked.

3. The method according to claim 2, wherein the hard mask pattern comprises a silicon nitride layer or silicon oxynitride (SiON) layer.

4. The method according to claim 1, wherein the first impurity ions are impurity ions of Group III.

5. The method according to claim 4, wherein the first impurity ions are implanted by an ion implantation method using about 0.2 to about 100 keV of energy.

6. The method according to claim 4, wherein the first impurity ions are implanted at a dose of about 1×10¹¹ to about 1×10¹⁶ ions/cm².

7. The method according to claim 1 further comprising:
forming a second photoresist pattern covering the N-MOS region and exposing the P-MOS region;
implanting second impurity ions into inner walls of the second preliminary trench, using the second photoresist pattern and the second mask pattern as ion implantation masks, thereby forming a second impurity layer, a portion of the second impurity layer being formed to extend below the second mask pattern; and
removing the second photoresist pattern.

8. The method according to claim 7, wherein etching the semiconductor substrate further forms a second impurity pattern of the second impurity layer remaining below the second mask pattern concurrently with the formation of the second trench.

9. The method according to claim 7, wherein the second impurity ions comprise boron (B), boron difluoride (BF₂), arsenic (As), phosphorus (P), or indium (In) ions.

10. The method according to claim 7, wherein the second impurity ions are implanted by an ion implantation method using about 0.2 to about 100 keV of energy.

11. The method according to claim 7, wherein the second impurity ions are implanted at a dose of about 1×10¹¹ to about 1×10¹⁶ ions/cm².

12. The method according to claim 7, further comprising annealing the semiconductor substrate having the first and second impurity layers formed thereon.

13. The method according to claim 12, wherein the annealing operation is performed at a temperature of 600° C. to 1000° C.

14. The method according to claim 1, wherein the operation of forming the trench isolation layer comprises:
forming an insulating layer for isolation filling the first and second trenches on an overall surface of the semiconductor substrate having the first and second trenches;
planarizing the insulating layer for isolation until the first and second mask patterns are exposed; and
removing the exposed first and second mask patterns, thereby exposing the semiconductor substrate.
